(19) United States
(12) Patent Application Publication
(10) Pub. No.: US 2025/0081544 A1
(43) Pub. Date: Mar. 6, 2025

(54) WIDE-BAND-GAP DIODE AND MANUFACTURING METHOD THEREOF

(71) Applicant: Taiwan-Asia Semiconductor Corporation, Hsinchu City (TW)

(72) Inventor: Di-Bao WANG, Hsinchu City (TW)

(21) Appl. No.: 18/644,400

(22) Filed: Apr. 24, 2024

(30) Foreign Application Priority Data
Aug. 30, 2023 (TW) 112132892

(51) Int. Cl. H01L 29/06; H01L 23/528; H01L 23/532; H01L 29/66

(52) U.S. Cl. CPC H10D 62/106; H01L 23/528; H01L 23/53214; H01L 23/53242; H10D 8/01

(57) ABSTRACT

A wide-band-gap diode and manufacturing method thereof are provided. The method of manufacturing a wide-band-gap diode involves growing an N-type doped epitaxial layer on an N-doped substrate. P-type ions are implanted into the epitaxial layer to form an active area, a junction termination extension region, and an edge region. The active area exhibits an axially symmetric graticule pattern, with higher doping area density towards the center of the active area. The junction termination extension region surrounds the active area, and the edge region encircles both of the active area and the junction termination extension region to enhance the wide-band-gap diode's capability to withstand surge currents.

### CROSS-REFERENCES TO RELATED APPLICATIONS

This application claims the benefit of priority to Taiwanese Patent Application No. 112132892 filed on Aug. 30, 2023, which is hereby incorporated by reference in its entirety.

### BACKGROUND OF THE INVENTION

### Field of the Invention

The present invention relates to a wide-band-gap diode, in particular to a wide-band-gap diode with an active area exhibiting an axially symmetric graticule-like pattern.

### Descriptions of the Related Art

Wide-band-gap diodes have the characteristics of wide-band-gap semiconductor materials and Schottky barrier. Wide-band-gap semiconductor materials, such as silicon carbide, gallium nitride, aluminum gallium nitride and zirconium nitride, have high electron drift speed, high electric field characteristics and high temperature tolerance. Schottky energy barriers typically have fast switching speeds and low forward voltage losses, making them suitable for high-frequency and high-speed switching applications. Therefore, a wide-band-gap diode that combines wide-band-gap semiconductor materials and Schottky energy barrier has better performance than other semiconductor materials under conditions of high power, high frequency, high temperature, and high pressure.

Junction barrier Schottky (JBS) and merged PiN Schottky (MPS) diodes currently using silicon carbide substrates can be used at voltages from 1200 volts to 1700 volts, high-power rectifier circuit with currents ranging from 20 amps to 200 amps and power ranging from 200 watts to 500 watts. For JBS/MPS diodes, the key performance indicators are the reverse breakdown voltage, the forward rated current and the forward surge current. The ability to withstand the forward surge current is a problem that this technology field has been trying to improve for many years.

In the existing technologies, plasma spreading layers (PSL), unbalance layout methods (ULM), and packaging enhancement are mainly used to improve the heat dissipation speed and the capability to withstand surge currents of wide-band-gap diodes. However, due to the plasma spreading layer and the unbalance layout method, the ratio of the Schottky contact to the Ohmic contact from the inside to the outside changes unevenly or the spatial symmetry is poor. Therefore, improvements still need to be made in terms of spreading current and improving the thermal conduction efficiency. In addition, using packaging to improve heat dissipation is costly and is not compatible with general packaging types.

In view of this, the present invention provides a wide-band-gap diode that optimizes the use of a plasma spreading layer and an unbalance layout method to increase the current spreading and improve the heat conduction efficiency for improving the capability to withstand surge currents of the wide-band-gap diode.

### SUMMARY OF THE INVENTION

The objective of the present invention is to provide a wide-band-gap diode and a manufacturing method thereof. In the present invention, the active area of the wide-band-gap diode is designed as a graticule-like pattern. Therefore, when a plasma spreading layer (PSL) and an unbalance layout method (ULM) are used to improve the heat dissipation speed and the capability to withstand surge currents, the ratio of Schottky contact to Ohmic contact changes more uniformly and continuously from the center of the active area to the outside thereof. Moreover, the graticule-like pattern has axial symmetry, so the spatial symmetry of the active area will be better.

To achieve the above objective, the present invention discloses a wide-band-gap diode which comprises a substrate, an epitaxial layer, an active area, a junction termination extension region, an edge region, an oxide layer, a first metal layer, an insulation layer, a protection layer, and a second metal layer. The substrate includes a first surface and a second surface. The epitaxial layer is disposed on the first surface of the substrate. The active area is disposed on the epitaxial layer and includes a plurality of doped regions and a plurality of undoped regions, wherein the doped regions and the undoped regions exhibit an axially symmetric graticule-like pattern. The junction termination extension region surrounds the active area and adjacent to the doped regions. The edge region is disposed in the epitaxial layer and encircles the active area. The oxide layer is disposed on the epitaxial layer and is etched to form an opening. The first metal layer is disposed in the opening to contact with the doped regions and acts as an anode of the wide-band-gap diode. The insulation layer is disposed on the oxide layer and the first metal layer. The protection layer covers the insulation layer. The second metal layer is disposed on the second surface of the substrate and acts as a cathode of the wide-band-gap diode.

In one embodiment of the present invention, wherein the graticule-like pattern is one of a circle and a hexagon.

In one embodiment of the present invention, wherein the edge region includes a plurality of field limitation rings (FLRs), the field limitation rings encircle the active area and the junction termination extension region, with an equal spacing among the field limitation rings, the doped regions of the active area have a first doping concentration, the junction termination extension region has a second doping concentration, the field limiting rings have a third doping concentration, the first doping concentration and the second doping concentration are the same, and the first doping concentration and the third doping concentration are different.

In one embodiment of the present invention, the edge region includes a plurality of field limitation rings, the field limitation rings encircle the active area and the junction termination extension region, and a spacing among the field limitation rings gradually increases in a direction away from the active area, the doped regions of the active area have a first doping concentration, the junction termination extension region has a second doping concentration, the field limiting rings have a third doping concentration, the first doping concentration and the second doping concentration are the same, and the first doping concentration and the third doping concentration are different.

In one embodiment of the present invention, the active area includes at least one surge protection region, and the surge protection region is free of ions doping to increase the capability to withstand surge currents of the wide-band-gap diode.

In one embodiment of the present invention, the substrate is made of one of silicon carbide, gallium oxide and zinc oxide.

In one embodiment of the present invention, the substrate and the epitaxial layer are both N-doped.

In one embodiment of the present invention, a material of the first metal layer is one of aluminum, titanium nitride and titanium.

In one embodiment of the present invention, material of the second metal layer is one of silver, nickel and titanium.

In addition, the present invention further disclosed a method of manufacturing a wide-band-gap diode which comprises the following steps: growing an epitaxial layer on a first surface of a substrate; doping a plurality of first ions spaced apart in the epitaxial layer to form a plurality of first doped regions, wherein a plurality of first undoped regions are defined among the first doped regions, an active area is formed both by the first doped regions and the first undoped regions, and the active area exhibits an axially symmetric graticule-like pattern; doping a plurality of second ions spaced apart in the epitaxial layer to form a junction termination extension region, surrounding the active area, and adjacent to the first doped regions; doping a plurality of third ions spaced apart in the epitaxial layer to form a plurality of second doped regions, wherein a plurality of second undoped regions are defined among the second doped regions, an edge region is formed both by the second doped regions and the second undoped regions, and the edge region encircling the junction termination extension region and the active area; depositing an oxide layer on the epitaxial layer; etching the oxide layer to form an opening; depositing a first metal layer in the opening to contact with the first doped regions and to act as an anode of the wide-band-gap diode; depositing an insulation layer on the oxide layer and the first metal layer; covering a protection layer on the insulation layer; and forming a second metal layer on a second surface of the substrate to act as a cathode of the wide-band-gap diode.

In one embodiment of the present invention, the graticule-like pattern is one of a circle and a hexagon.

In one embodiment of the present invention, the edge region includes a plurality of field limitation rings (FLRs), the field limitation rings encircle the active area and the junction termination extension region, with an equal spacing among the field limitation rings, and the doped regions of the active area have a first doping concentration. The junction termination extension region has a second doping concentration, the field limiting rings have a third doping concentration, the first doping concentration and the second doping concentration are the same, and the first doping concentration and the third doping concentration are different.

In one embodiment of the present invention, the edge region includes a plurality of field limitation rings, the field limitation rings encircle the active area and the junction termination extension region, and a spacing among the field limitation rings gradually increases in a direction away from the active area. The doped regions of the active area have a first doping concentration, the junction termination extension region has a second doping concentration, the field limiting rings have a third doping concentration, the first doping concentration and the second doping concentration are the same, and the first doping concentration and the third doping concentration are different.

In one embodiment of the present invention, the active area includes at least one surge protection region, and the surge protection region is free of ions doping to increase the capability to withstand surge currents of the wide-band-gap diode.

After referring to the drawings and the embodiments as described in the following, those the ordinary skilled in this art can understand other objectives of the present invention, as well as the technical means and embodiments of the present invention.

### BRIEF DESCRIPTION OF THE DRAWINGS

FIG. 1 is a cross-sectional view of the manufacturing process of the wide-band-gap diode according to the present invention;

FIG. 2 is a cross-sectional view of the manufacturing process of the wide-band-gap diode according to the present invention;

FIG. 3 is a top view of the wide-band-gap diode according to the present invention;

FIG. 4 is a cross-sectional view of the manufacturing process of the wide-band-gap diode according to the present invention;

FIG. 5 is a cross-sectional view of the manufacturing process of the wide-band-gap diode according to the present invention;

FIG. 6 is a cross-sectional view of the manufacturing process of the wide-band-gap diode according to the present invention;

FIG. 7 is a cross-sectional view of the manufacturing process of the wide-band-gap diode according to the present invention;

FIG. 8 is a cross-sectional view of the manufacturing process of the wide-band-gap diode according to the present invention;

FIG. 9 is a cross-sectional view of the manufacturing process of the wide-band-gap diode according to the present invention;

FIG. 10 is a top view of the wide-band-gap diode according to the present invention;

FIG. 11 is a schematic diagram of the wide-band-gap diode on a wafer according to the present invention;

FIG. 12 is a schematic diagram of the wide-band-gap diode on a wafer according to the present invention;

FIG. 13 is a top view of the wide-band-gap diode according to the present invention;

FIG. 14 is a top view of the wide-band-gap diode according to the present invention;

FIG. 15 is a top view of the wide-band-gap diode according to the present invention;

FIG. 16 is a flowchart of the manufacturing method of the wide-band-gap diode according to the present invention; and

FIG. 17 is a flowchart of the manufacturing method of the wide-band-gap diode according to the present invention.

### DETAILED DESCRIPTION OF THE PREFERRED EMBODIMENT

In the following description, the present invention will be explained with reference to various embodiments thereof. These embodiments of the present invention are not intended to limit the present invention to any specific environment, application or particular method for implementations described in these embodiments. Therefore, the description of these embodiments is for illustrative purposes only and is not intended to limit the present invention. It shall be appreciated that, in the following embodiments and the attached drawings, a part of elements not directly related to the present invention may be omitted from the illustration, and dimensional proportions among individual elements and the numbers of each element in the accompanying drawings are provided only for ease of understanding but not to limit the present invention.

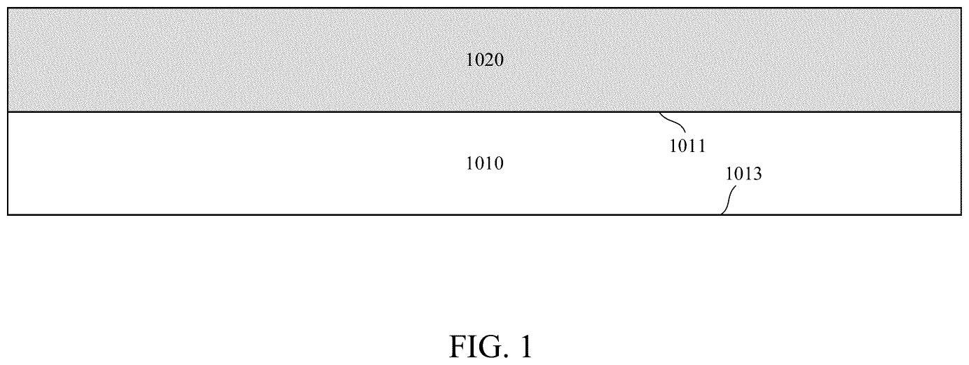

The first embodiment of the present invention is illustrated in FIG. 1 through FIG. 9. The wide-band-gap diode 1000 includes a substrate 1010, an epitaxial layer 1020, an active area 1030, a junction termination extension (JTE) region 1023, an edge region 1050, an oxide layer 1060, a first metal layer 1070, an insulation layer 1080, a protection layer 1090, and a second metal layer 1100. The substrate 1010 has a first surface 1011 and a second surface 1013.

Through the design of the photomask pattern, the active area 1030 of the wide-band-gap diode 1000 in the present invention exhibits an axially symmetric graticule-like pattern. The P-doped regions at the center (inner side) and outer side of the active area 1030 are adjacent. When a surge current penetrates the P-N junction, electric charge can drift outward through the P-doped regions. Additionally, the design using the graticule-like pattern allows the ohmic proportion of the active area to decrease gradually from the inside to the outside, facilitating the outward heat conduction. Therefore, the wide-band-gap diode 1000 of the present invention enhances the immediate spreading effect and heat dissipation effect against the surge current.

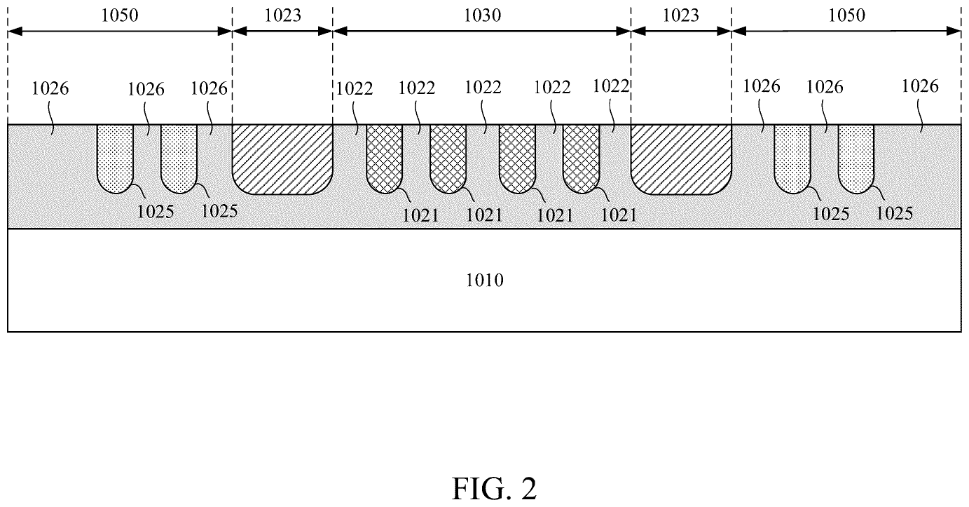

Specifically, please refer to FIG. 1 to FIG. 9, which depict cross-sectional views of the wide-band-gap diode 1000 at different stages of the manufacturing process. In the process of manufacturing the wide-band-gap diode 1000 of the present invention, first, an epitaxial layer 1020 is grown on the first surface 1011 of the substrate 1010, then, a plurality of first ions are spaced apart doped into the epitaxial layer 1020 to form a plurality of first doped regions 1021, and a plurality of second ions are spaced apart doped into the epitaxial layer 1020 to form a junction termination extension region 1023. A plurality of third ions are spaced apart doped into the epitaxial layer 1020 to form a plurality of second doped regions 1025, as shown in FIG. 1 to FIG. 2.

In this embodiment, both the substrate 1010 and the epitaxial layer 1020 are N-doped. The substrate 1010 is made of one of silicon carbide, gallium oxide, and zinc oxide. The first doped regions 1021, the junction termination extension region 1023, and the second doped regions 1025 are P-type doped regions formed by implanting P-type ions, such as boron ions, aluminum ions, gallium ions, indium ions, etc., which are ions with positive charges, into the N-type epitaxial layer.

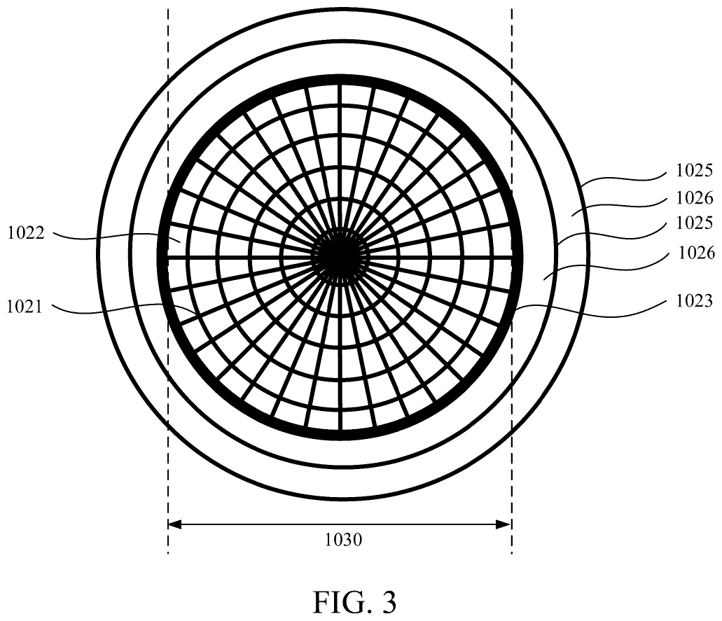

Please refer to FIG. 2 and FIG. 3. FIG. 3 depicts a top view of the active area 1030, the junction termination extension region 1023, and the edge region 1050. The boundaries of the first doped regions 1021 define a plurality of first undoped regions 1022, and the active area 1030 is formed by both the first doped regions 1021 and the first undoped regions 1022. The first undoped regions 1022 refer to the regions where P-type ions are not implanted. In other words, the first undoped regions 1022 are the portions of the epitaxial layer 1020 located within the active area 1030. The active area 1030 exhibits an axially symmetric graticule-like pattern. In this embodiment, the graticule-like pattern is a circular pattern. The junction termination extension region 1023 is adjacent to the first doped regions 1021 and surrounds the active area 1030 to enhance the insulation effect, thereby improving the capability of withstanding high voltages of the wide-band-gap diode 1000.

Similarly, please refer to FIG. 2 and FIG. 3 again. The boundaries of the second doped regions 1025 define a plurality of second undoped regions 1026, and the edge region 1050 is formed by both the second doped regions 1025 and the second undoped regions 1026. The second undoped regions 1026 refer to the regions where P-type ions are not implanted. In other words, the second undoped regions 1026 are the portions of the epitaxial layer 1020 located within the edge region 1050. The edge region 1050 surrounds the junction termination extension region 1023 and the active area 1030, and is used to limit electric field diffusion to reduce the risk of electric field concentration and voltage breakdown.

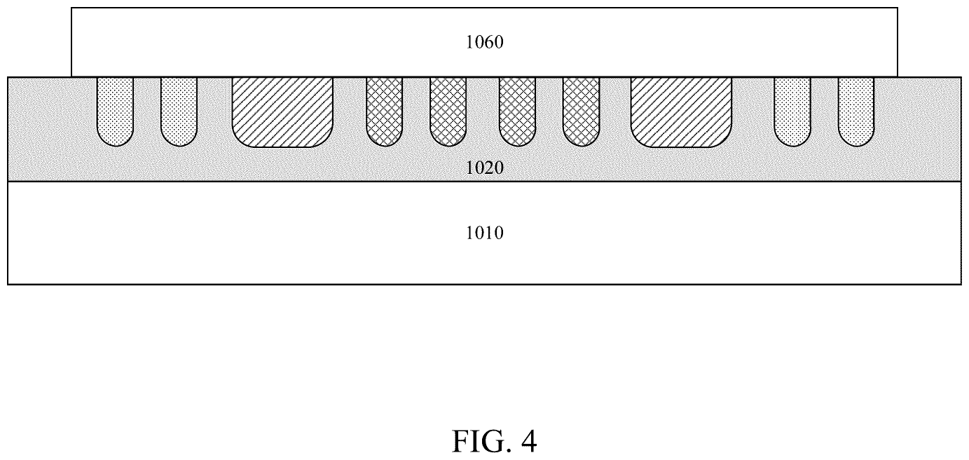

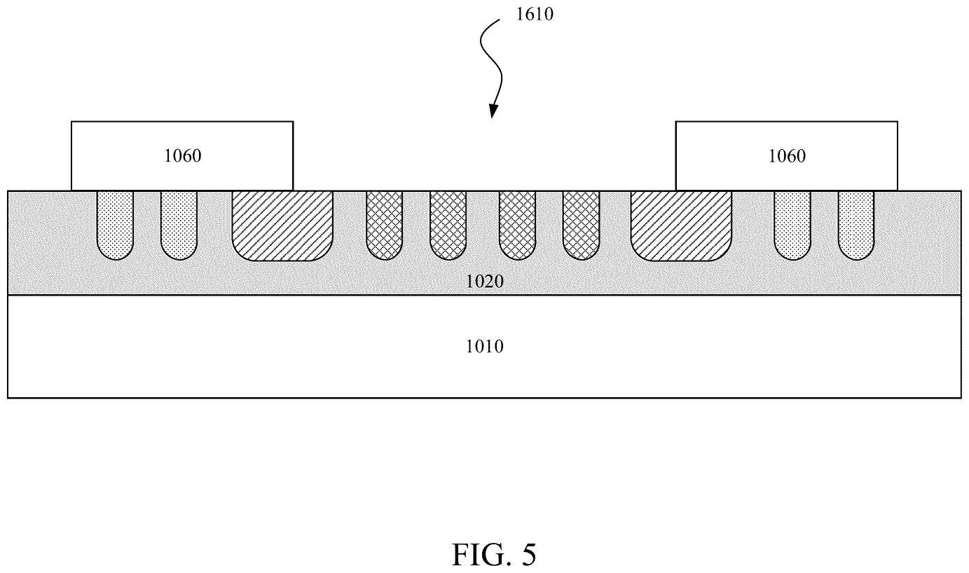

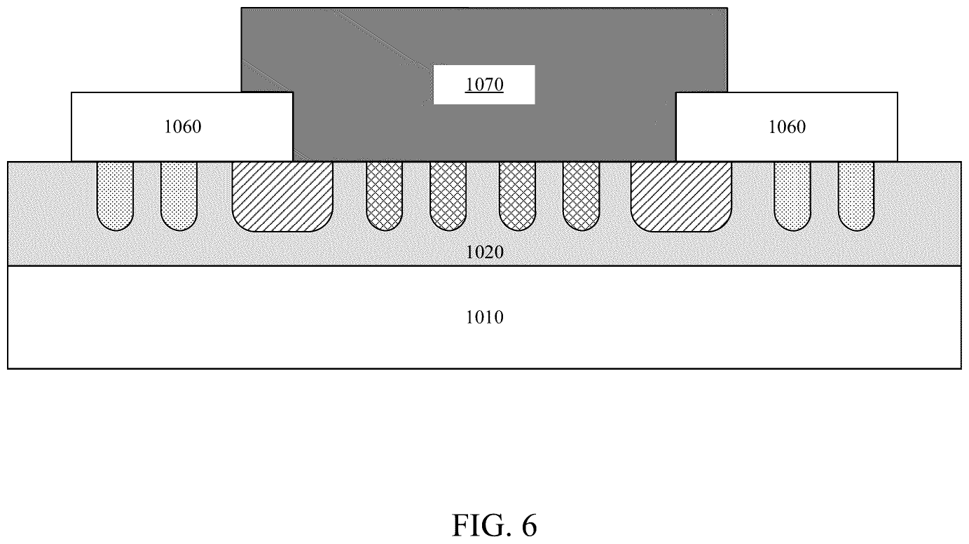

An oxide layer 1060 is deposited on the epitaxial layer 1020, and the oxide layer 1060 is etched to form an opening 1610, as shown in FIG. 4 and FIG. 5. A first metal layer 1070 is deposited in the opening 1610 to contact the first doped regions 1021 and act as an anode of the wide-band-gap diode 1000, as shown in FIG. 6. The material of the first metal layer 1070 may be aluminum, titanium nitride, or titanium.

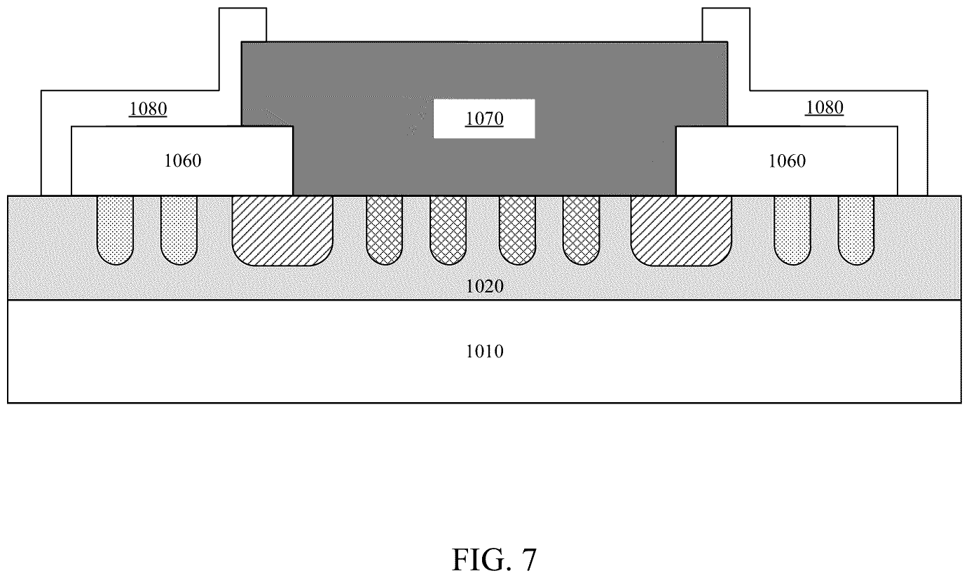

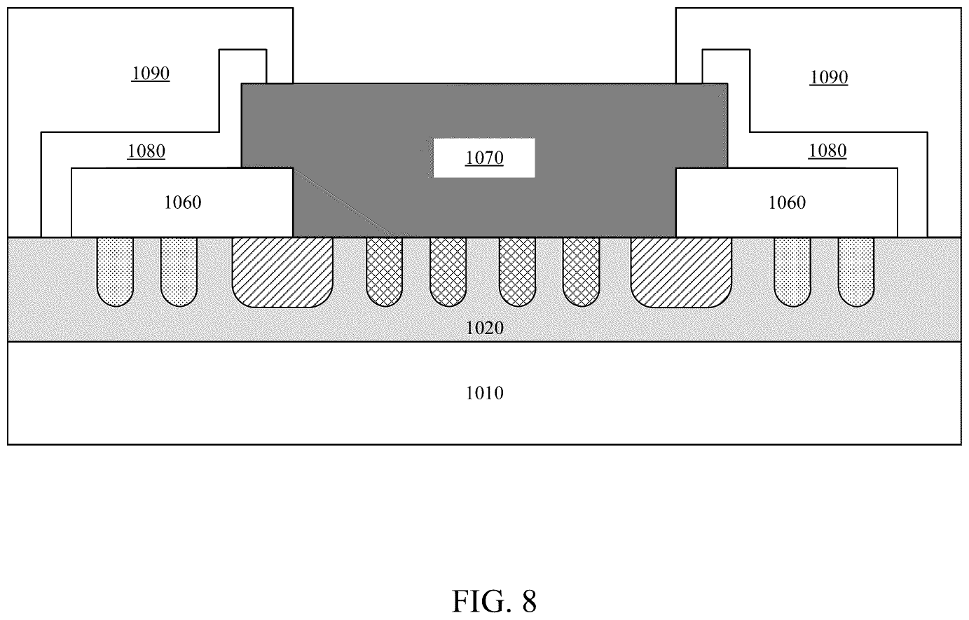

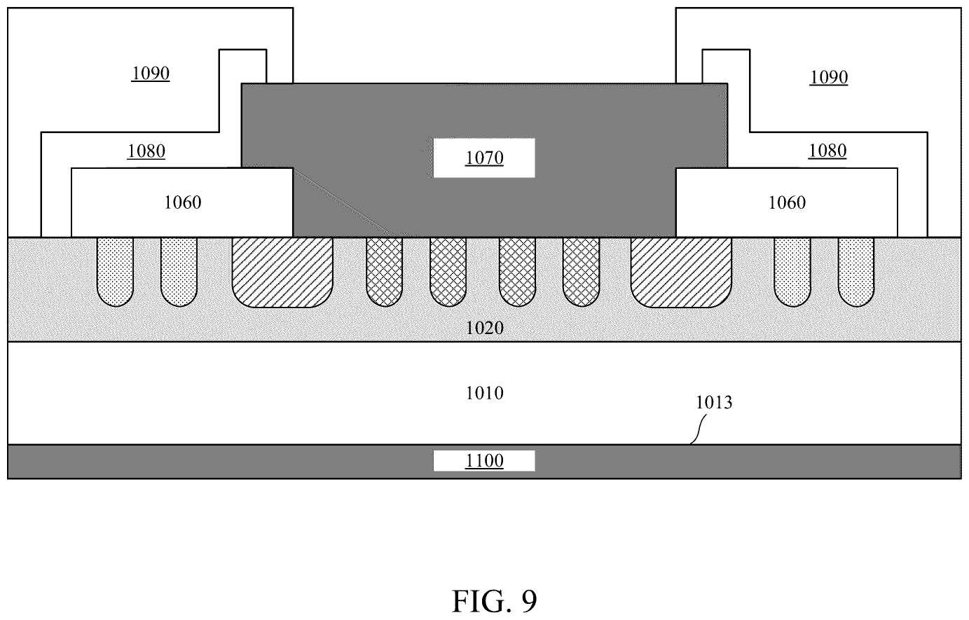

Next, an insulation layer 1080 is deposited on the oxide layer 1060 and the first metal layer 1070, and a protective layer 1090 is coated on the insulation layer 1080, as shown in FIG. 7 and FIG. 8. Finally, a second metal layer 1100 is disposed on a second surface 1013 of the substrate 1010 to act as a cathode of the wide-band-gap diode 1000, as shown in FIG. 9. The material of the second metal layer 1100 may be silver, nickel, or titanium.

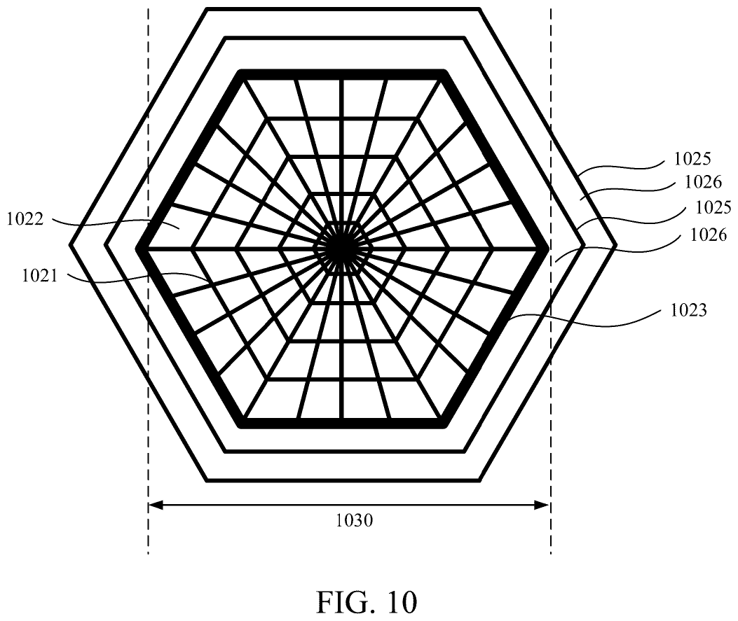

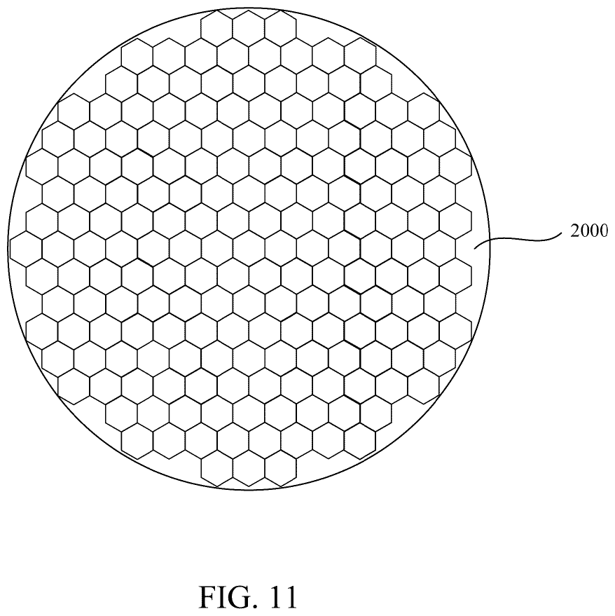

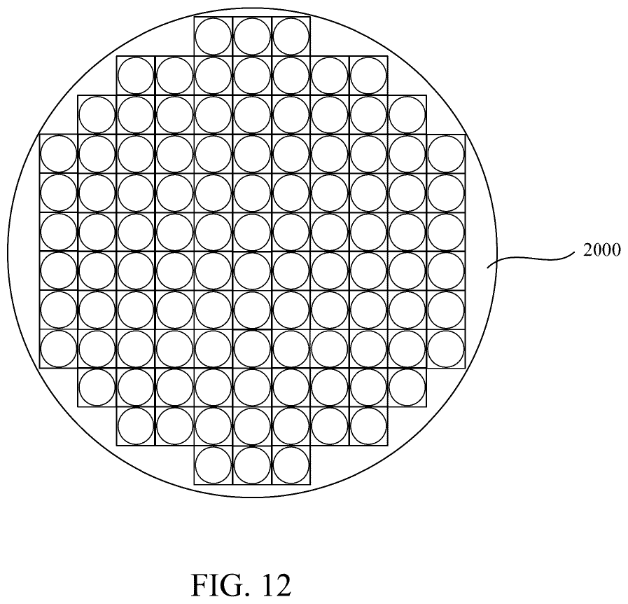

The second embodiment of the present invention is illustrated in FIG. 3 and FIG. 10 to FIG. 12. The second embodiment is an extension of the first embodiment. FIG. 10 depicts another implementation of the graticule-like pattern. Unlike the circular graticule-like pattern in the first embodiment, in this embodiment, the graticule-like pattern is hexagonal. Specifically, refer to FIG. 11 and FIG. 12, which respectively illustrate schematic diagrams of arrangements of hexagonal and circular graticule-like patterns fabricated on a wafer. Due to limitations in wafer cutting technology, when the graticule-like pattern is circular, multiple chips on the wafer are typically cut using the smallest square at the periphery of the wafer. However, when the graticule-like pattern is a polygon, such as the hexagon shown in FIG. 10, plasma cutting technology can be used along the edge of the wafer. Comparing the hexagonal and circular graticule-like patterns, more hexagonal patterns can be accommodated on the same-sized wafer 2000. Therefore, in this embodiment, the use of hexagonal graticule-like patterns further reduces the manufacturing cost of the wide-band-gap diode 1000.

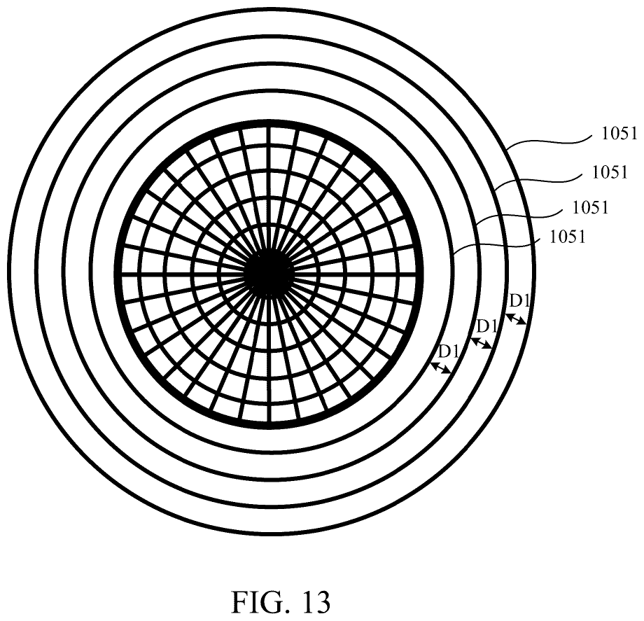

The third embodiment of the present invention is illustrated in FIG. 13. The third embodiment is an extension of the first and second embodiments. In this embodiment, the edge region 1050 includes a plurality of field limitation rings (FLRs) 1051. The FLRs 1051 encircle the active area 1030 and the junction termination extension region 1023, with an equal spacing D1 between each FLR 1051.

Each first doped region 1021 in the active area 1030 has a first doping concentration, the junction termination extension region 1023 has a second doping concentration, and each FLR 1051 has a third doping concentration. The first doping concentration and the second doping concentration are the same, while the first doping concentration and the third doping concentration are different. In other embodiments, the first doping concentration may differ from the second doping concentration, and both the first and second doping concentrations are less than the third doping concentration.

It should be noted that in FIG. 13, the graticule-like pattern is depicted as a circle pattern for illustration purposes. In other embodiments where the graticule-like pattern is a hexagonal pattern, the design of this embodiment can be applied as well.

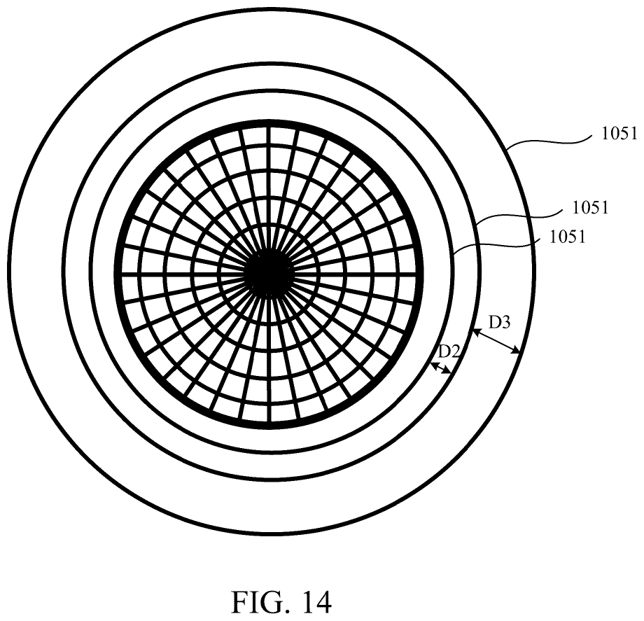

The fourth embodiment of the present invention is illustrated in FIG. 14. This embodiment is an extension of the first through the third embodiments. Unlike the third embodiment, where the distances D1 between each field limitation ring 1051 are all the same. In this embodiment, the distances between each field limitation ring 1051 gradually increase in a direction away from the active area 1030. Specifically, as shown in FIG. 14, the distance D2 between the two field limitation rings closer to the active area 1030 is smaller than the distance D3 between the two field limitation rings outer. In this configuration, the wide-band-gap diode designed with the graticule-like pattern in FIG. 14 exhibits greater tolerance to the surge current compared to the wide-band-gap diode designed with the graticule-like pattern in FIG. 13.

It should be noted that while FIG. 14 illustrates the graticule-like pattern as circular, the design presented in this embodiment can also be applied when the graticule-like pattern is hexagonal in other embodiments.

Furthermore, it should be noted that the number of field limitation rings and the ratio of doped to undoped regions in the active area, as depicted in the aforementioned embodiments and figures, are provided for illustrative purposes only and are not intended to limit the present invention. In actual applications, the number of field limitation rings and the ratio of doped to undoped regions in the active area can be adjusted according to the circuitry or electronic components paired with the wide-band-gap diode.

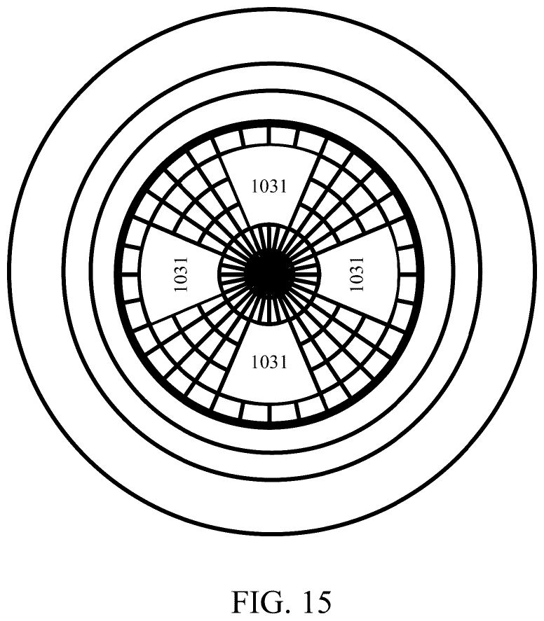

The fifth embodiment of the present invention, as shown in FIG. 15, is an extension from the third and fourth embodiments. In this embodiment, the active area 1030 includes at least one surge protection region 1031. The surge protection region 1031 is free of ions doping and is designed to increase the surge current so that the capability to withstand surge currents of the wide-band-gap diode 1000 will be increased accordingly.

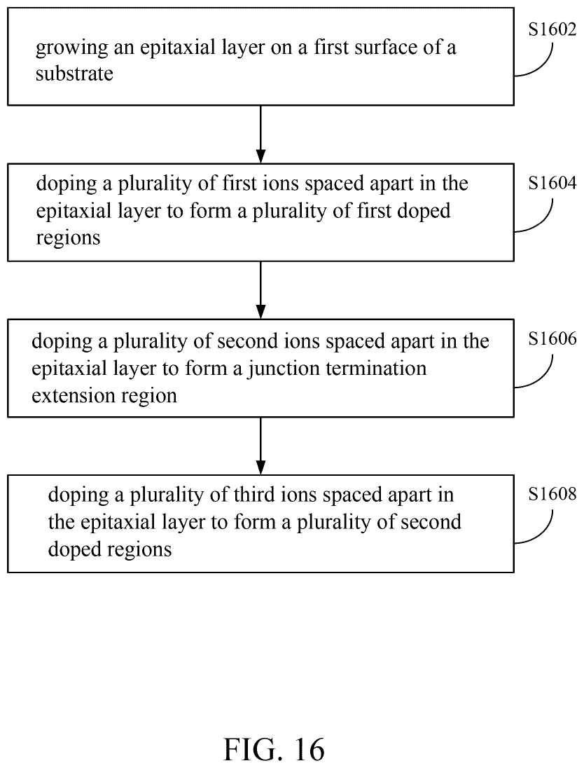

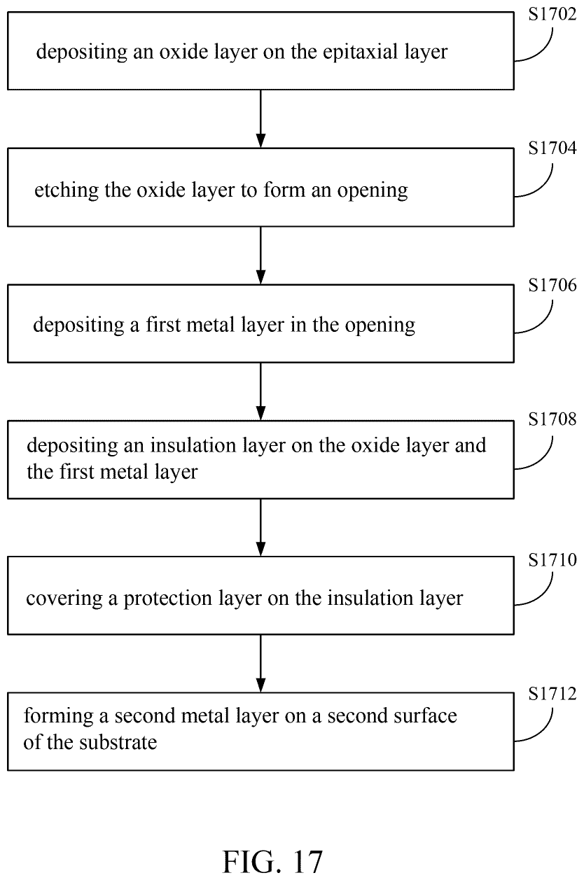

The sixth embodiment of the present invention, as depicted in FIG. 16 and FIG. 17, is the flowchart of the manufacturing method for the wide-band-gap diode of the present invention. This manufacturing method is applicable to produce the wide-band-gap diode 1000 described in the previous embodiments. The manufacturing method for the wide-band-gap diode involves the use of various semiconductor equipment, including but not limited to deposition equipment, ion implantation machines, photolithography equipment, etching equipment, cleaning equipment, sputtering machines, testing equipment, and packaging equipment.

Firstly, in step 1602, an epitaxial layer is grown on a first surface of a substrate. In step 1604, a plurality of first ions are spaced apart implanted into the epitaxial layer to form a plurality of first doped regions. In step 1606, a plurality of second ions are spaced apart implanted into the epitaxial layer to form a junction termination extension region. In step 1608, a plurality of third ions are spaced apart implanted into the epitaxial layer to form a plurality of second doped regions.

Next, in step 1702, an oxide layer is deposited on the epitaxial layer. In step 1704, the oxide layer is etched to form an opening. In step 1706, a first metal layer is deposited in the opening. In step 1708, an insulation layer is deposited on the oxide layer and the first metal layer. In step 1710, a protective layer is coated to cover the insulation layer. In step 1712, a second metal layer is disposed on a second surface of the substrate.

In one embodiment, the graticule-like pattern is fabricated as either a circle or a hexagon.

In other embodiments, the edge region includes a plurality of field limitation rings. These field limitation rings encircle the active area and the junction termination extension region, with an equal spacing between each of them. The doped regions within the active area have a first doping concentration. The junction termination extension region has a second doping concentration. The field limitation rings have a third doping concentration. The first doping concentration is the same as the second doping concentration, while the first doping concentration is different from the third doping concentration.

In other embodiments, the edge region includes a plurality of field limitation rings that encircle the active area and the junction termination extension region, with the spacing between each of them gradually increasing in one direction away from the active area. The doped regions within the active area have a first doping concentration. The junction termination extension region has a second doping concentration. The field limitation rings have a third doping concentration. The first doping concentration is the same as the second doping concentration, while the first doping concentration is different from the third doping concentration.

In other embodiments, the active area includes at least one surge protection region, which is free of ions doping to increase the capability to withstand surge currents of the wide-band-gap diode.

In addition to the above steps, the wide-band-gap diode manufacturing method of this embodiment can also perform all the operations described in the previous embodiments and have all corresponding functions. Those skilled in the art would readily understand how to carry out such operations and have such functions based on the embodiments described above, so no further explanation is provided.

The above embodiments are used only to illustrate the implementations of the present invention and to explain the technical features of the present invention, and are not used to limit the scope of the present invention. Any modifications or equivalent arrangements that can be easily accomplished by people skilled in the art are considered to fall within the scope of the present invention, and the scope of the present invention should be limited by the claims of the patent application.

What is claimed is:

1. A wide-band-gap diode, comprising:
a substrate, including a first surface and a second surface;
an epitaxial layer, growing on the first surface of the substrate;
an active area, disposed on the epitaxial layer, and including a plurality of doped regions and a plurality of undoped regions, wherein the doped regions and the undoped regions exhibit an axially symmetric graticule-like pattern;
a junction termination extension region, surrounding the active area, and adjacent to the doped regions;
an edge region, disposed in the epitaxial layer and encircling the active area;
an oxide layer, disposed on the epitaxial layer and being etched to form an opening;
a first metal layer, disposed in the opening, contacting with the doped regions, and acting as an anode of the wide-band-gap diode;
an insulation layer, disposed on the oxide layer and the first metal layer;
a protection layer, covering the insulation layer; and
a second metal layer, disposed on the second surface of the substrate, and acting as a cathode of the wide-band-gap diode.

2. The wide-band-gap diode of claim 1, wherein the graticule-like pattern is one of a circle and a hexagon.

3. The wide-band-gap diode of claim 1, wherein the edge region includes a plurality of field limitation rings (FLRs), the field limitation rings encircle the active area and the junction termination extension region, with an equal spacing among the field limitation rings.

4. The wide-band-gap diode of claim 3, wherein the doped regions of the active area have a first doping concentration, the junction termination extension region has a second doping concentration, the field limiting rings have a third doping concentration, the first doping concentration and the second doping concentration are the same, and the first doping concentration and the third doping concentration are different.

5. The wide-band-gap diode of claim 1, wherein the edge region includes a plurality of field limitation rings, the field limitation rings encircle the active area and the junction termination extension region, and a spacing among the field limitation rings gradually increases in a direction away from the active area.

6. The wide-band-gap diode of claim 5, wherein the doped regions of the active area have a first doping concentration, the junction termination extension region has a second doping concentration, the field limiting rings have a third doping concentration, the first doping concentration and the second doping concentration are the same, and the first doping concentration and the third doping concentration are different.

7. The wide-band-gap diode of claim 1, wherein the active area includes at least one surge protection region, and the surge protection region is free of ions doping to increase the capability to withstand surge currents of the wide-band-gap diode.

8. The wide-band-gap diode of claim 1, wherein the substrate is made of one of silicon carbide, gallium oxide and zinc oxide.

9. The wide-band-gap diode of claim 1, wherein the substrate and the epitaxial layer are both N-doped.

10. The wide-band-gap diode of claim 1, wherein a material of the first metal layer is one of aluminum, titanium nitride and titanium.

11. The wide-band-gap diode of claim 1, wherein a material of the second metal layer is one of silver, nickel and titanium.

12. A method of manufacturing a wide-band-gap diode, comprising:
growing an epitaxial layer on a first surface of a substrate;
doping a plurality of first ions spaced apart in the epitaxial layer to form a plurality of first doped regions, wherein a plurality of first undoped regions are defined among the first doped regions, an active area is formed both by the first doped regions and the first undoped regions, and the active area exhibits an axially symmetric graticule-like pattern;
doping a plurality of second ions spaced apart in the epitaxial layer to form a junction termination extension region, surrounding the active area, and adjacent to the first doped regions;
doping a plurality of third ions spaced apart in the epitaxial layer to form a plurality of second doped regions, wherein a plurality of second undoped regions are defined among the second doped regions, an edge region is formed both by the second doped regions and the second undoped regions, and the edge region encircling the junction termination extension region and the active area;
depositing an oxide layer on the epitaxial layer;
etching the oxide layer to form an opening;
depositing a first metal layer in the opening to contact with the first doped regions and to act as an anode of the wide-band-gap diode;
depositing an insulation layer on the oxide layer and the first metal layer;
covering a protection layer on the insulation layer; and
forming a second metal layer on a second surface of the substrate to act as a cathode of the wide-band-gap diode.

13. The method of claim 12, wherein the graticule-like pattern is one of a circle and a hexagon.

14. The method of claim 12, wherein the edge region includes a plurality of field limitation rings, the field limitation rings encircle the active area and the junction termination extension region, with an equal spacing among the field limitation rings.

15. The method of claim 14, wherein the doped regions of the active area have a first doping concentration, the junction termination extension region has a second doping concentration, the field limiting rings have a third doping concentration, the first doping concentration and the second doping concentration are the same, and the first doping concentration and the third doping concentration are different.

16. The method of claim 12, wherein the edge region includes a plurality of field limitation rings, the field limitation rings encircle the active area and the junction termination extension region, and a spacing among the field limitation rings gradually increases in a direction away from the active area.

17. The method of claim 16, wherein the doped regions of the active area have a first doping concentration, the junction termination extension region has a second doping concentration, the field limiting rings have a third doping concentration, the first doping concentration and the second doping concentration are the same, and the first doping concentration and the third doping concentration are different.

18. The manufacturing method of claim 12, wherein the active area includes at least one surge protection region, and the surge protection region is free of ions doping to increase the capability to withstand surge currents of the wide-band-gap diode.
